(19) United States
(12) Patent Application Publication
(10) Pub. No.: US 2013/0231901 A1
(43) Pub. Date: Sep. 5, 2013

(54) WELL PAD PLACEMENT

(71) Applicants: Zhengang Lu, Katy, TX (US); Elena Valova, Houston, TX (US); Martin Crick, Abingdon (GB)

(72) Inventors: Zhengang Lu, Katy, TX (US); Elena Valova, Houston, TX (US); Martin Crick, Abingdon (GB)

(21) Appl. No.: 13/596,540

(22) Filed: Aug. 28, 2012

Related U.S. Application Data
(60) Provisional application No. 61/534,926, filed on Sep. 15, 2011.

(51) Int. Cl. E21B 43/30; G06F 3/0481; G06F 17/50

(52) U.S. Cl. CPC E21B 43/30; G06F 17/5004; G06F 3/0481
USPC 703/1; 166/245; 715/762

(57) ABSTRACT

A method can include assigning one or more constraints to an upper surface, assigning one or more constraints to a lower surface, defining a pad configuration, generating pad locations locatable on the upper surface that conform to the defined pad configuration and the assigned constraints for the upper surface and the lower surface, and outputting specifications at least one of the generated pad locations. Various other apparatuses, systems, methods, etc., are also disclosed.

### RELATED APPLICATIONS

This application claims the benefit of U.S. Provisional Application Ser. No. 61/534,926 filed Sep. 15, 2011, entitled “Well Pad Placement”, which is incorporated by reference herein.

### BACKGROUND

Various industries rely on underground or subsurface placement of piping and other equipment. For example, in the oil and gas industry, a rig or pad to place equipment underground may be located on a ground surface proximate to a reservoir. As to offshore rigs or pads, these may be floating structures or structures with supports that extend to a seabed (a ground surface) to place equipment below a sea surface (a water surface) and below a seabed. Placement of such equipment can depend on any of a variety of factors. Various technologies and techniques described herein pertain to equipment placement.

### SUMMARY

A method can include assigning constraints associated with an environment and generating rig or pad placement options. Such constraints may account for physical factors of an environment, physical factors of a rig or a pad, cost factors, legal factors or other factors. A method can optionally output specifications for a placement option, for example, to facilitate building a rig or pad. A computer-readable storage medium can include instructions to instruct a computing system to receive constraint information for a multilayer model of an environment, receive configuration information for a drilling pad, and generate a ranking of drilling pad locations based on the constraint information, the configuration information and the multilayer model of the environment. A computer-readable storage medium can include instructions to instruct a computing system to generate one or more graphical user interfaces for selection of regional geometry constraints for an environment, for selection of pad and well specifications for the environment, for selection of pad placement options for placement of pads in the environment, and for selection of presenting a cost surface or presenting pad locations. Various other apparatuses, systems, methods, etc., are also disclosed.

This summary is provided to introduce a selection of concepts that are further described below in the detailed description. This summary is not intended to identify key or essential features of the claimed subject matter, nor is it intended to be used as an aid in limiting the scope of the claimed subject matter.

### BRIEF DESCRIPTION OF THE DRAWINGS

Features and advantages of the described implementations can be more readily understood by reference to the following description taken in conjunction with the accompanying drawings.

FIG. 1 illustrates an example system that includes various components for simulating and optionally interacting with a geological environment;

FIG. 2 illustrates an example of an environment that includes various equipment and various features, which may be represented at one or more levels;

FIG. 3 illustrates an example of method for generating pad locations;

FIG. 4 illustrates an example of a method for providing placement options for one or more pads;

FIG. 5 illustrates examples of graphical user interfaces for interacting with a pad placement process;

FIG. 6 illustrates examples of modules and graphical user interfaces for pad placement and design;

FIG. 7 illustrates an example of a graphical user interface;

FIG. 8 illustrates an example of a graphical user interface;

FIG. 9 illustrates example modules and an example of a graphical user interface that includes a pad placement option implemented as a plug-in with respect to a framework;

FIG. 10 illustrates an example of a graphical user interface for selecting geometric restrictions as inputs for a pad placement process;

FIG. 11 illustrates an example of a graphical user interface for geometric modeling of one or more restrictions using a three-dimensional grid;

FIG. 12 illustrates an example of a graphical user interface for a cost functions associated with a geometric restriction;

FIG. 13 illustrates an example of a graphical user interface for selecting pad and well specifications as inputs for a pad placement process;

FIG. 14 illustrates an example of a graphical user interface for selecting placement options for a pad placement process;

FIG. 15 illustrates an example of a scenario to perform sensitivity analysis, optimization or other processes;

FIG. 16 illustrates an example of a graphical user interface for rendering information associated with pad placement and restrictions; and

FIG. 17 illustrates example components of a system and a networked system.

### DETAILED DESCRIPTION

The following description includes the best mode presently contemplated for practicing the described implementations. This description is not to be taken in a limiting sense, but rather is made merely for the purpose of describing the general principles of the implementations. The scope of the described implementations should be ascertained with reference to the issued claims.

As mentioned, various industries rely on underground or subsurface placement of piping and other equipment and placement of such equipment can depend on any of a variety of factors. For example, an underground rock formation or existing underground equipment may be considered obstacles to avoid or that introduce costs (e.g., drilling through the rock, removing or relocating existing equipment, etc.). Other factors can include property rights such as leasehold boundaries, public infrastructure (e.g., roads, power lines, communication lines, etc.), and even moving obstacles such as ice formations (e.g., icebergs).

A pad may be a formation or structure to be located or placed for purposes of performing one or more types of underground or subsurface operations. For example, in the oil and gas industry a ground surface pad may be a temporary drilling site constructed of materials such as gravel, shell or wood. Such materials may be local materials (e.g., sourced locally for reasons of cost, environmental impact, etc.). For some long-drilling-duration operations, deep wells, such as the ultradeep wells of western Oklahoma, or some regulatory jurisdictions such as The Netherlands, a pad may be constrained, for example, as having to be paved with asphalt or concrete. For temporary pads, after a drilling operation is over, most of a pad may optionally be removed, plowed back into the ground, etc.

A rig may be a machine used to drill a bore such as a wellbore. In onshore operations, a rig may include various types of support equipment. Major components of a rig can include mud tanks, mud pumps, a derrick or mast, drawworks, a rotary table or topdrive, a drillstring, power generation equipment and auxiliary equipment. Offshore, a rig can include various components, for example, as for an onshore rig. For offshore operations, a pad may be a vessel or drilling platform itself while the rig may be referred to as a drilling package.

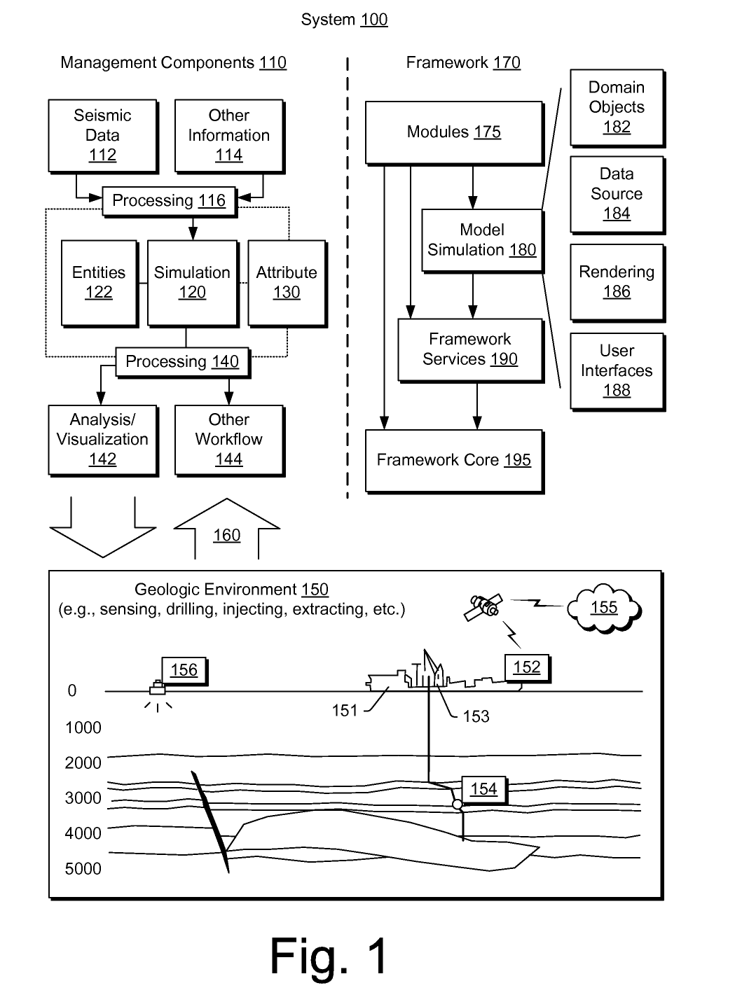

To facilitate explanation of various examples of pad or rig placement processes and related processes, FIG. 1 shows an example of a system 100 that includes various management components 110 to manage various aspects of a geologic environment 150. For example, the management components 110 may allow for direct or indirect management of sensing, drilling, injecting, extracting, etc., with respect to the geologic environment 150. In turn, further information about the geologic environment 150 may become available as feedback 160 (e.g., optionally as input to one or more of the management components 110).

In the example of FIG. 1, the geologic environment 150 may include a vessel 151 as a pad equipped with a rig 153. The environment 150 may be outfitted with any of a variety of sensors, detectors, actuators, etc. For example, equipment 152 may include communication circuitry to receive and to transmit information with respect to one or more networks 155. Such information may include information associated with downhole equipment 154, which may be equipment to acquire information, to assist with resource recovery, etc. Other equipment 156 may be located remote from a well site and include sensing, detecting, emitting or other circuitry. Such equipment may include storage and communication circuitry to store and to communicate data, instructions, etc.

As to the management components 110 of FIG. 1, these may include a seismic data component 112, an information component 114, a pre-simulation processing component 116, a simulation component 120, an attribute component 130, a post-simulation processing component 140, an analysis/visualization component 142 and a workflow component 144. In operation, seismic data and other information provided per the components 112 and 114 may be input to the simulation component 120, optionally with pre-simulation processing via the processing component 116 and optionally with post-simulation processing via the processing component 140.

As an example, the simulation component 120 may include entities 122. Entities 122 may be earth entities or geological objects such as wells, surfaces, reservoirs, etc. In the system 100, the entities 122 can include entities that provide for virtual representations of actual physical entities, for example, that are reconstructed for purposes of simulation. The entities 122 may be based on data acquired via sensing, observation, etc. (e.g., the seismic data 112 and other information 114).

As an example, the simulation component 120 may include a software framework such as an object-based framework. In such a framework, entities may be based on pre-defined classes to facilitate modeling and simulation. A commercially available example of an object-based framework is the MICROSOFT® .NET™ framework (Redmond, Wash.), which provides a set of extensible object classes. In the .NET™ framework, an object class encapsulates a module of reusable code and associated data structures. Object classes can be used to instantiate object instances for use in by a program, script, etc. For example, borehole classes may define objects for representing boreholes based on well data.

In the example of FIG. 1, the simulation component 120 may process information to conform to one or more attributes specified by the attribute component 130, which may be a library of attributes. Such processing may occur prior to input to the simulation component 120. Alternatively, or in addition to, the simulation component 120 may perform operations on input information based on one or more attributes specified by the attribute component 130. As an example, the simulation component 120 may construct one or more models of the geologic environment 150, which may be used for simulation of behavior of the geologic environment 150 (e.g., responsive to one or more acts, whether natural or artificial). In the example of FIG. 1, the analysis/visualization component 142 may allow for interaction with a model or model-based results. Additionally, or alternatively, output from the simulation component 120 may be input to one or more other workflows, as indicated by a workflow component 144. A workflow may include worksteps, for example, where each workstep acts upon input to provide an output (e.g., input may be data and output may be a visualization of the data, an analysis of the data, etc.). In the example of FIG. 1, dotted lines indicate possible feedback within the management components 110. For example, feedback may occur between the analysis/visualization component 142 and either one of the processing components 116 and 140.

As an example, the management components 110 may include features of a commercially available simulation framework such as the PETREL® seismic to simulation software framework (Schlumberger Limited, Houston, Texas). The PETREL® framework provides components that allow for optimization of exploration and development operations. The PETREL® framework includes seismic to simulation software components that can output information for use in increasing reservoir performance, for example, by improving asset team productivity. Through use of such a framework, various professionals (e.g., geophysicists, geologists, and reservoir engineers) can develop collaborative workflows and integrate operations to streamline processes. Such a framework may be considered an application and may be considered a data-driven application (e.g., where data is input for purposes of simulating a geologic environment).

As an example, the management components 110 may include features for geology and geological modeling to generate high-resolution geological models of reservoir structure and stratigraphy (e.g., classification and estimation, facies modeling, well correlation, surface imaging, structural and fault analysis, well path design, data analysis, fracture modeling, workflow editing, uncertainty and optimization modeling, petrophysical modeling, etc.). Particular features may allow for performance of rapid 2D and 3D seismic interpretation, optionally for integration with geological and engineering tools (e.g., classification and estimation, well path design, seismic interpretation, seismic attribute analysis, seismic sampling, seismic volume rendering, geobody extraction, domain conversion, etc.). As to reservoir engineering, for a generated model, one or more features may allow for simulation workflow to perform streamline simulation, reduce uncertainty and assist in future well planning (e.g., uncertainty analysis and optimization workflow, well path design, advanced gridding and upscaling, history match analysis, etc.). The management components 110 may include features for drilling workflows including well path design, drilling visualization, and real-time model updates (e.g., via real-time data links).

As an example, various aspects of the management components 110 may be add-ons or plug-ins that operate according to specifications of a framework environment. For example, a commercially available framework environment marketed as the OCEAN® framework environment (Schlumberger Limited, Houston, Tex.) allows for seamless integration of add-ons (or plug-ins) into a PETREL® framework workflow. The OCEAN® framework environment leverages .NET® tools (Microsoft Corporation, Redmond, Wash.) and offers interfaces for development. As an example, various components may be implemented as add-ons (or plug-ins) that conform to and operate according to specifications of a framework environment (e.g., according to application programming interface (API) specifications, etc.).

FIG. 1 also shows an example of a framework 170 that includes a model simulation layer 180 along with a framework services layer 190, a framework core layer 195 and a modules layer 175. The framework 170 may be the commercially available OCEAN® framework where the model simulation layer 180 is the commercially available PETREL® model-centric software package that hosts OCEAN® framework applications.

In the example of FIG. 1, the model simulation layer 180 may provide domain objects 182, act as a data source 184, provide for rendering 186 and provide for various user interfaces 188. Rendering 186 may provide a graphical environment in which applications can display their data while the user interfaces 188 may provide a common look and feel for application user interface components.

In the example of FIG. 1, the domain objects 182 can include entity objects, property objects and optionally other objects. Entity objects may be used to geometrically represent wells, surfaces, reservoirs, etc., while property objects may be used to provide property values as well as data versions and display parameters. For example, an entity object may represent a well where a property object provides log information as well as version information and display information (e.g., to display the well as part of a model).

In the example of FIG. 1, data may be stored in one or more data sources (or data stores, generally physical data storage devices), which may be at the same or different physical sites and accessible via one or more networks. The model simulation layer 180 may be configured to model projects. As such, a particular project may be stored where stored project information may include inputs, models, results and cases. Thus, upon completion of a modeling session, a user may store a project. At a later time, the project can be accessed and restored using the model simulation layer 180, for example, which may recreate instances of the relevant domain objects.

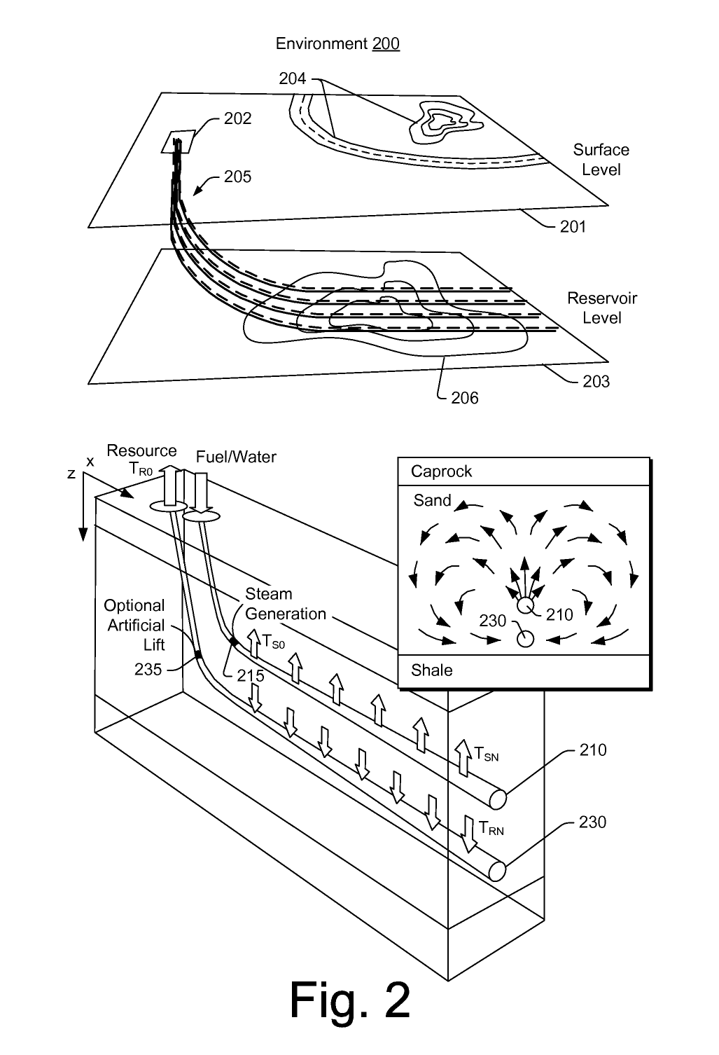

FIG. 2 shows an example of an environment 200 that may be modeled using a multilayer model. For example, such a model may include a surface level 201 (e.g., upper surface or layer) and a reservoir level 203 (e.g., lower surface or layer). As shown in FIG. 2, a structure 202 may be placed (e.g., built) on the surface level 201 for drilling or operating subsurface equipment 205 for exploring, injecting, extracting, etc. Further, placement of the structure 202 may aim to account for various constraints such as roads, soil conditions, etc. As shown, the structure 202 may be, for example, a pad for a rig or rigs (e.g., to drill, to place equipment, to operate equipment, etc.).

In the example of FIG. 2, the equipment 205 may be steam assisted gravity drainage (SAGD) equipment for injecting steam and extracting resources from a reservoir 206. For example, a SAGD operation can include a steam-injection well 210 and a resource production well 230. In the example of FIG. 2, a downhole steam generator 215 generates steam in the injection well 210, for example, based on supplies of water and fuel from surface conduits, and optional artificial lift equipment 235 (e.g., ESP, etc.) may be implemented to facilitate resource production. While a downhole steam generator is shown, steam may be alternatively, or additionally, generated at the surface level. As illustrated in a cross-sectional view, the steam rises in the subterranean portion. As the steam rises, it transfers heat to a desirable resource such as heavy oil. As the resource is heated, its viscosity decreases, allowing it to flow more readily to the resource production well 230.

As to pad placement in such an environment for a SAGD enhanced oil recovery (EOR) operation, various factors may be relevant. For example, area swept by a SAGD set, spacing between wells, etc. As an example, a model can optionally account for such factors when determining one or more possible pad placement locations (or rig placement locations). As an example, where a pad or pads are mentioned, specifications, configurations, etc., for other locatable equipment may be substituted for a pad or pads. As an example, specifications, configurations, etc., may be provided for various types of locatable equipment (e.g., structures or other equipment) and placement locations for such equipment ascertained (e.g., consider ascertaining practical or optimal locations).

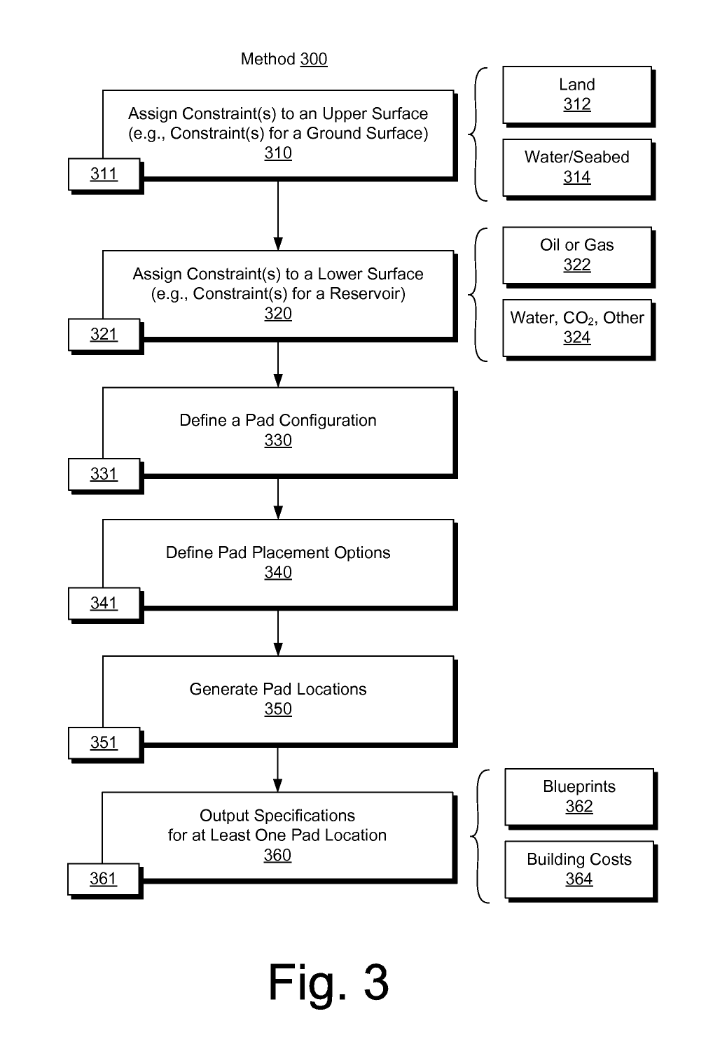

FIG. 3 shows an example of method 300 for generating pad locations. The method 300 includes an assignment block 310 to assign one or more constraints to an upper surface (e.g., a land surface 312 or a water or seabed surface 314), an assignment block 320 to assign one or more constraints to a lower surface (e.g., associated with an oil or gas reservoir 322 or water, CO₂ or other reservoir 324), a definition block 330 to define a pad configuration, a definition block 340 to define pad placement options, a generation block 350 to generate pad locations and an output block 360 to output specifications for at least one pad location (e.g., as blueprints 362, building costs 364, etc.).

The method 300 is shown in FIG. 3 in association with various computer-readable media (CRM) blocks 311, 321, 331, 341, 351 and 361. Such blocks generally include instructions suitable for execution by one or more processors (or cores) to instruct a computing device or system to perform one or more actions. While various blocks are shown, a single medium may be configured with instructions to allow for, at least in part, performance of various actions of the method 300. As an example, a computer-readable medium (CRM) may be a computer-readable storage medium. One or more CRM block may be provided for graphical user interfaces (GUIs), etc.

As an example, a method can include assigning one or more constraints to an upper surface, assigning one or more constraints to a lower surface, defining a pad configuration, generating pad locations locatable on the upper surface that conform to the defined pad configuration and the assigned constraints for the upper surface and the lower surface, and outputting specifications at least one of the generated pad locations. In such a method, assigning one or more constraints to an upper surface or a lower surface may include assigning one or more cost constraints or assigning one or more physical, environmental constraints. As an example, a lower surface may be a two-dimensional representation of a reservoir and an upper surface may be a two-dimensional representation of a ground or other surface (e.g., a surface suitable for one or more pad placement locations).

As to generating pad locations, a method may include generating locations based at least in part on parameter values determined by applying a probe to locations on the upper surface. Such a probe may be a two-dimensional probe (e.g., with a footprint based on one or more pad configuration definition specifications) or a three-dimensional probe (e.g., of an appropriate depth dimension to consider one or more features defined or definable within a subsurface volume). As an example, a method may include a combination of two-dimensional and three-dimensional probes.

As an example, a method may include defining a probe based at least in part on a defined pad configuration and applying the probe to locations on an upper surface to determine parameter values, for example, where such values can indicate whether or to what degree a location is acceptable for placement of a pad. As an example, a method may include generating pad locations locatable on an upper surface and ranking locations on the upper surface based at least in part on determined parameter values (e.g., as determined by applying a probe). As mentioned, other types of equipment may substitute for a pad and, as such, a probe may represent specifications, a configuration, etc., for equipment other than a pad.

As an example, constraints may be assigned to more than two surfaces or, for example, be defined in a three-dimensional manner and/or optionally defined with a dimension such as time (e.g., one spatial dimension and a time dimension, two spatial dimensions and time dimension, three spatial dimensions and a time dimension). As to a time dimension, consider a development, which may be planned or not but that may expand with respect to time, which may be a period of years. Where an operation or operations extend over a period of years, a constraint that varies with respect to time may be applied for one or more times. As to three spatial dimensions, where three dimensional constraint information is available (e.g., accessible via a data source, measurements, interpolation, etc.), as an example, a three-dimensional probe may be implemented. As an example, a three-dimensional probe may be implemented as a secondary process (e.g., fine tuning, confirmation, etc.), for example, to focus in on a region of concern after application of a two- dimensional probe.

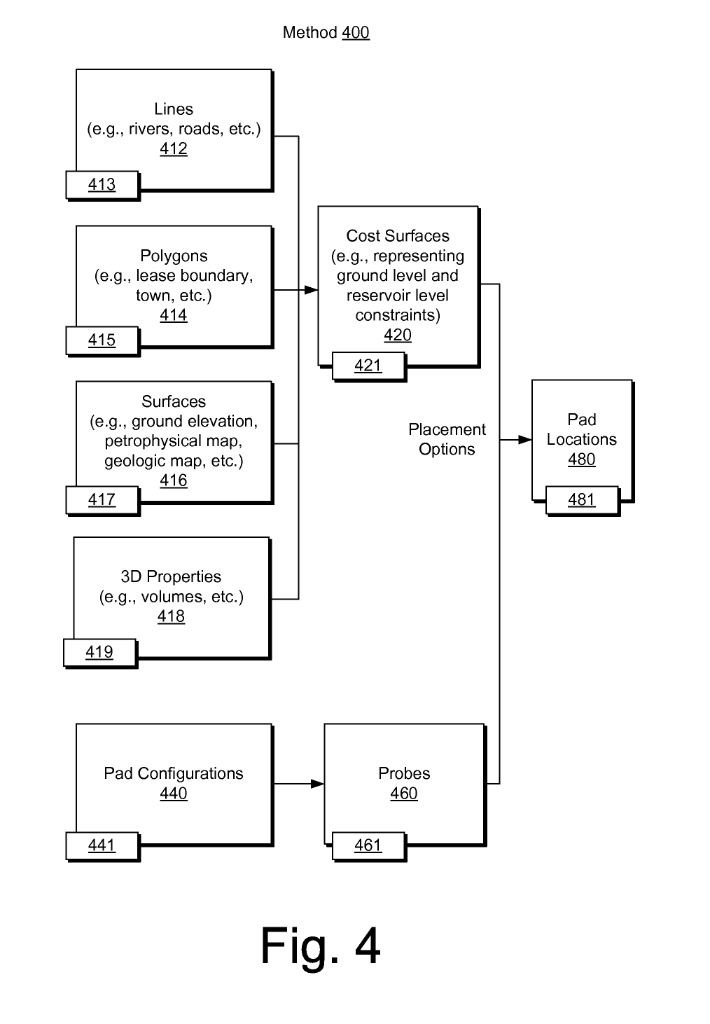

FIG. 4 shows an example of a method 400 for providing placement options for one or more pads. The method 400 includes various blocks 412, 414, 416 and 418 for assigning constraints as well as to define one or more pad configurations 441. As shown in the example of FIG. 4, the constraints are provided as input to a cost block 420 that forms one or more cost surfaces, for example, for a ground level and a reservoir level. Along another branch of the method 400, the pad configuration information is received as input to a probe block 460 that constructs a probe or probes to probe the one or more cost surfaces of the cost block 420. Upon application of the probe to the one or more costs surfaces, the method 400 can output placement options as pad locations, as indicated by a pad location or output block 480.

The method 400 is shown in FIG. 4 in association with various computer-readable media (CRM) blocks 413, 415, 417, 419, 421, 441, 461 and 481. Such blocks generally include instructions suitable for execution by one or more processors (or cores) to instruct a computing device or system to perform one or more actions. While various blocks are shown, a single medium may be configured with instructions to allow for, at least in part, performance of various actions of the method 400. As an example, a computer-readable medium (CRM) may be a computer-readable storage medium. One or more CRM block may be provided for graphical user interfaces (GUIs), etc.

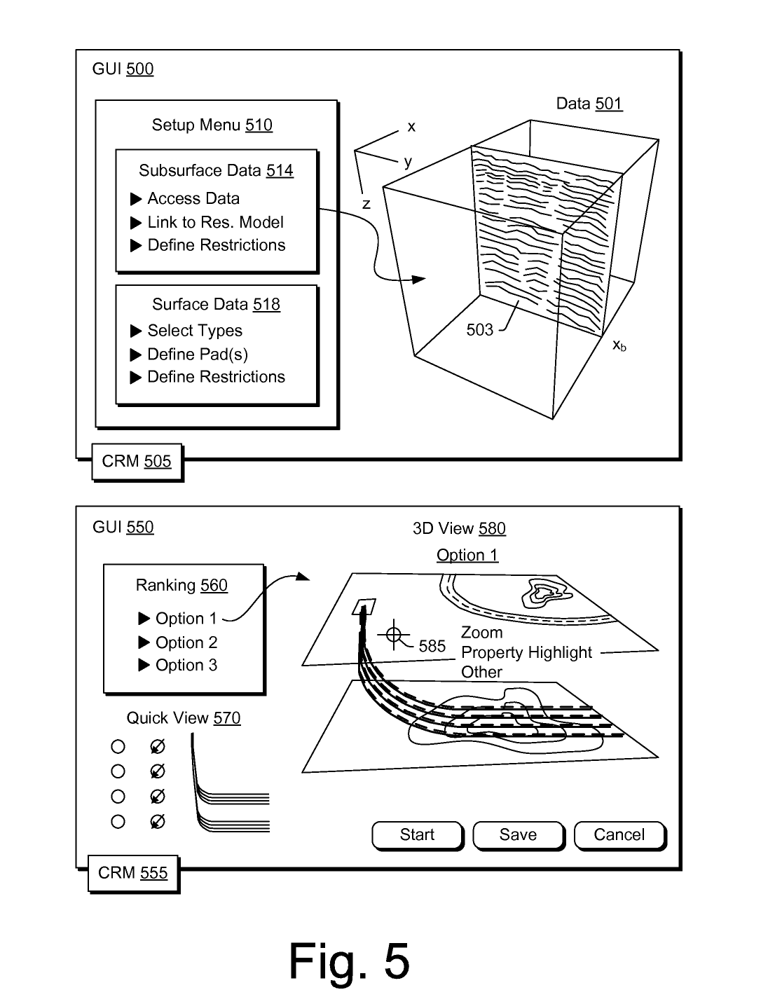

FIG. 5 shows examples of graphical user interfaces (GUIs) 500 and 550 for interacting with a pad placement process. In the GUI 500, a portion may present a representation of data 501 for an environment, for example, sliceable along various planes 503. Further, the GUI 500 may present a setup menu 510 that allows for input of subsurface data 514 and surface data 518. In FIG. 5, the GUI 550 may present various information related to output from a method such as the method 400 of FIG. 4. For example, a ranking graphic 560 may present a ranking of placement options, a quick view graphic 570 may present a simplified view of a placement option and a multidimensional view 580 may present details of a placement option, optionally responsive to selection of one of the ranked placement options via the ranking graphic 560. As shown, the graphic 580 may include a cursor 585 that allows for zooming, rotating, panning, display of properties, highlighting of properties, pad specifications, estimated pad costs, estimated pad building time, or other functions. In the example of FIG. 5, the quick view graphic 570 shows two sets of equipment, which may be, for example, equipment associated with a SAGD or other EOR operation.

The GUI 500 and the GUI 550 are shown in FIG. 5 in association with various computer-readable media (CRM) blocks 505 and 555. Such blocks generally include instructions suitable for execution by one or more processors (or cores) to instruct a computing device or system to perform one or more actions. While various blocks are shown, a single medium may be configured with instructions to allow for, at least in part, performance of various actions such as rendering, controlling, inputting, outputting, etc. As an example, a computer-readable medium (CRM) may be a computer-readable storage medium.

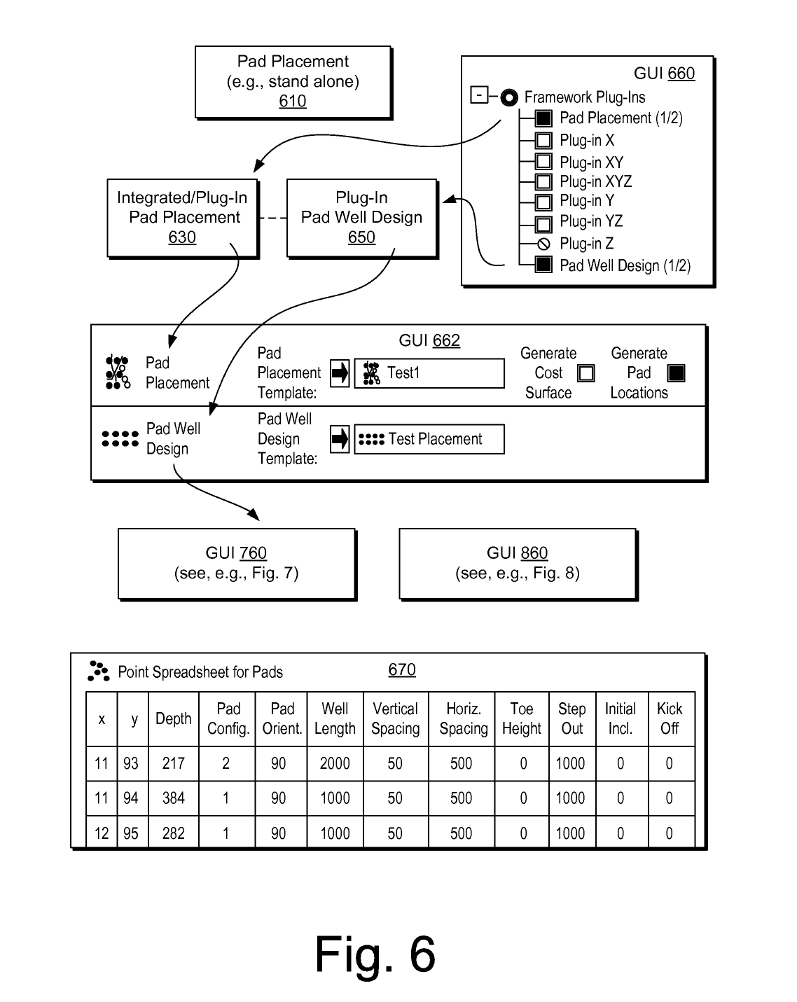

Various examples of graphical user interfaces (GUIs) are shown in FIGS. 6 to 16. In such examples, a pad placement module (e.g., as a plug-in to a framework) may be used in conjunction with a pad well design module (e.g., as a plug-in to a framework). A graphic from a pad placement process may include markers that identify well head points, for example, resulting from an analysis that accounts for one or more constraints. Such a graphic may illustrate potential wells to be drilled from a well point or points and optionally one or more other features (e.g., other wells, obstacles, constraints, etc.). As an example, surface and reservoir restrictions may be show using color coding for features such as pre-existing wells, surface acreage available, a reservoir target area, roads, rivers, etc.

As an example, a pad placement module may operate in conjunction with a pad well design module in a manner that first identifies and characterizes possible surface pad locations, and second, creates one or more wells underneath a pad. A process may, for example, generate thousands of wells following restrictions at a ground level (e.g., an upper surface) and a reservoir level (e.g., a lower surface).

As an example, a pad placement module may interoperate with a framework such as the PETREL® framework, for example, to generate pad surface locations. As an example, a user may customize pad well configurations, restrictions pertinent to ground level and reservoir level, and create one or more cost schemes. A pad placement module may include functionality to perform one or more sensitivity studies, for example, on well length, orientation, etc. As an example, integration with a pad well design module may allow for creation of wells at one or more identified surface pad locations. As an example, a process for determining a field development plan can include performing one or more pad placement processes.

As to restrictions, as an example, one or more restrictions can be described using lines, polygons, regular surfaces, etc., and applied at, for example, a reservoir level (e.g., lower surface) or a ground level (e.g., upper surface). As an example, one or more cost functions may indicate where an allowable drilling area is or, for example, may implement a cost structure. As an example, a pad placement process may demonstrate cost to drill in relationship to one or more features (e.g., a pad being located closer to a river, a road, etc.). As to a geometric restriction, a pad placement process can include assigning a cost function (e.g., a cost structure).

As an example, a user may specify which pad configuration or configurations to use along with well parameters and one or more strategies for computations for a pad placement process. As an example, pad well parameters can be used to indicate total aerial space a pad configuration may occupy where, for example, the same parameters may be used with a pad well design module. As an example, a pad index attribute can optionally be created to indicate occupied pad locations and to show which pads have less than maximum well lengths. Such an attribute may be used with a pad well design module, for example, to help truncate one or more wells based on one or more pad placement restrictions.

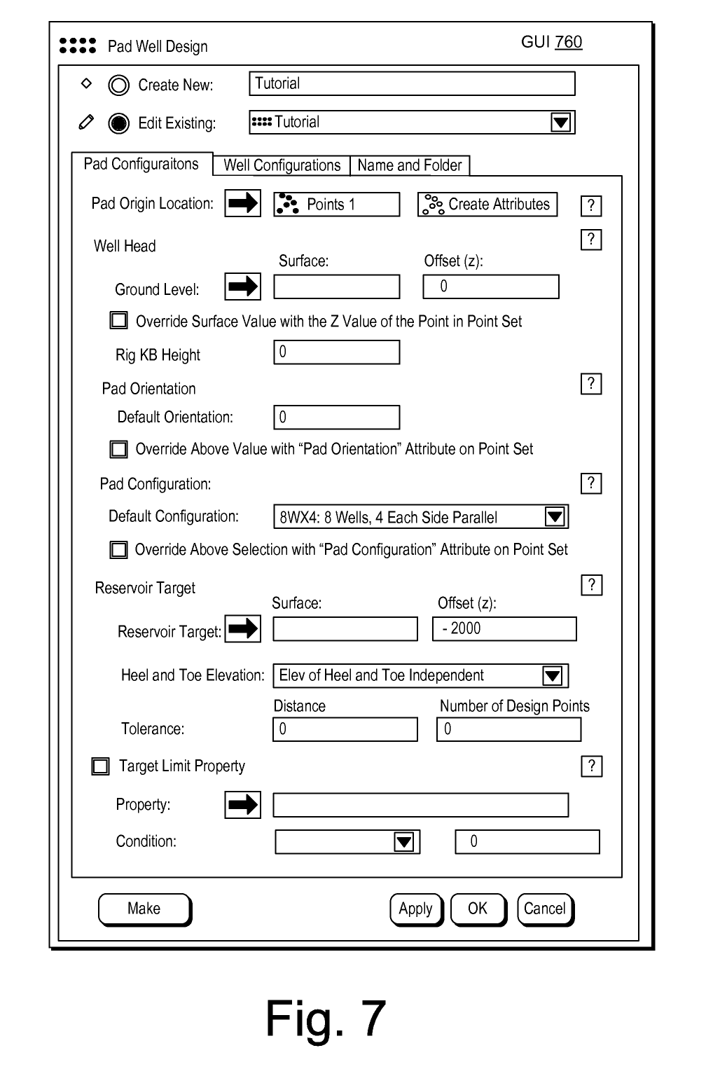

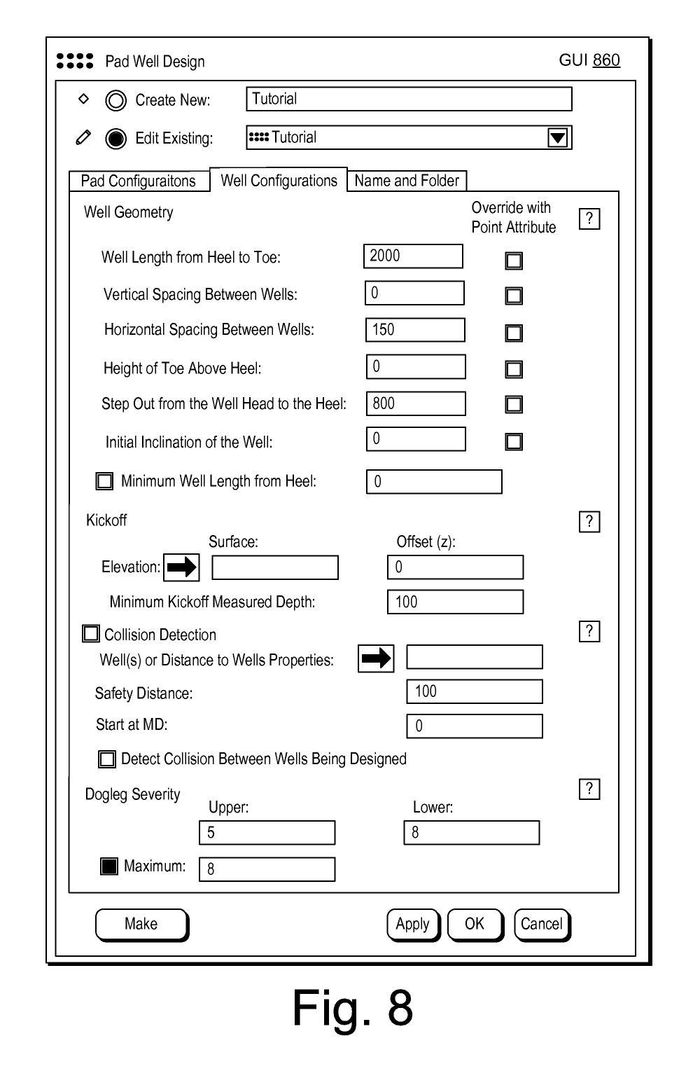

FIG. 6 shows examples of some modules 610, 630 and 650, graphical user interfaces 660, 662, 760 and 860 for pad placement and design and an example of a spreadsheet 670, which may be editable by a user or otherwise processed, analyzed, exported, etc. As shown, various implementations or arrangements are possible for pad placement modules. The pad placement module 610 may be a stand-alone module while the module 630 may be an integrated or plug-in module that optionally receives or transmits or otherwise exchanges data (directly or indirectly) with the module for pad well design 650. The GUIs 660 and 662 provide for selection of a pad placement or pad well design process. The GUIs 760 and 860 pertain to various aspects of pad well design, for example, as shown in FIG. 7 and FIG. 8, respectively.

As to the GUI 660, in the example of FIG. 6, it includes a framework plug-in option that extends a list of options in a tree type of arrangement. As indicated, a Pad Placement option and a Pad Well Design option are selected, along with various other options. The GUI 662 shows information and controls rendered for Pad Placement and Pad Well Design. As to Pad Placement, a template control may be activated to select a template (e.g., “Test1”) and, for example, an option to generate a cost surface or an option to generate pad locations may be selected. As to Pad Well Design, a template control may be activated to select a template (e.g., “Test Placement”).

FIG. 7 shows an example of the GUI 760. In the example of FIG. 7, control graphics provide for creation of a new pad well design or editing of an existing pad well design. The GUI 760 also includes tabs for rendering information and controls germane to pad configurations, well configurations and name and folder options. In the example of FIG. 7, the tab for pad configurations is selected. Rendered controls can include a pad origin location control for points and attributes, a ground level control for surface and offset, a rig height control, a pad orientation control, a control for pad configuration (e.g., number of wells, sides parameters, etc.), a control for a reservoir target for a surface, offset, heel and toe elevation, tolerance (e.g., distance, number of design points, etc.) and a control for one or more target limit properties (e.g., to select a property, assign a condition, etc.). Control buttons may be provided to “make” a pad well design, to “apply” selections and/or field entries, to “OK” selections and/or entries, to “cancel” selections and/or entries, etc.

FIG. 8 shows an example of the GUI 860. In the example of FIG. 8, control graphics provide for creation of a new pad well design or editing of an existing pad well design. The GUI 860 also includes tabs for rendering information and controls germane to pad configurations, well configurations and name and folder options. In the example of FIG. 8, the tab for well configurations is selected. Rendered controls can include a well length from heel to toe control, a vertical spacing between wells control, a horizontal spacing between wells control, a height of toe above heel control, a step out from a well head to a heel control an initial inclination of a well control, a minimum well length from heel control, kickoff controls for elevation and minimum kickoff measured depth, collision detection controls for well or distance to well properties, a safety distance, etc., and a dogleg severity control. Control buttons may be provided to “make” a configuration file, etc., to “apply” selections and/or field entries, to “OK” selections and/or entries, to “cancel” selections and/or entries, etc.

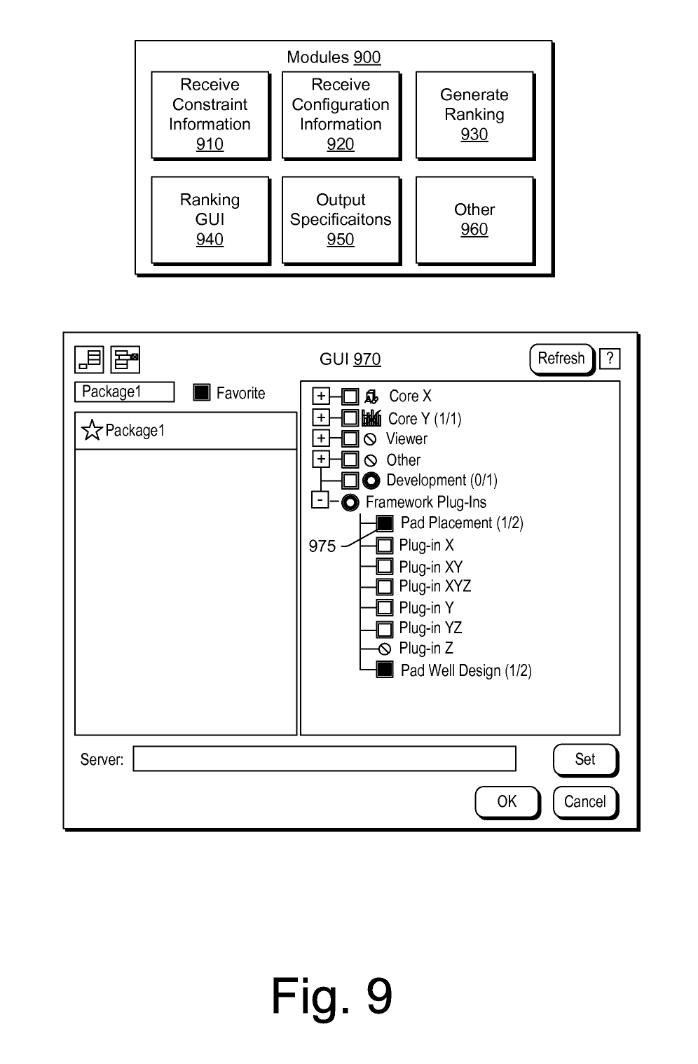

FIG. 9 shows example modules 900 and an example of a graphical user interface 970 that includes a pad placement option 975 implemented as a plug-in with respect to a framework. As an example, the modules 900 may be configured as one or more computer-readable media (e.g., storage media) with processor-executable instructions to instruct a computing system to: receive constraint information for a multilayer model of an environment (see, e.g., module 910); receive configuration information for a drilling pad (see, e.g., module 920); generate a ranking of drilling pad locations based on the constraint information, the configuration information and the multilayer model of the environment (see, e.g., module 930); present, via a graphical user interface, at least some of the ranked drilling pad locations (see, e.g., module 940); and output specifications for at least one of the drilling pad locations based on input received via the graphical user interface (see, e.g., module 950). One or more other modules 960 may be included in the modules 700.

As an example, a module may include instructions to instruct a computing system to output specifications to output a blueprint of a building site for building a drilling pad at one of the drilling pad locations, to output a building costs for building a drilling pad at one of the drilling pad locations, to output operational specifications for operation of equipment that may be placed via the drilling pad location, etc. A module may be provided that includes instructions to receive configuration information for a drilling pad where the information is for an offshore drilling pad.

As an example, a module or modules may be in the form of one or more computer-readable media that include processor-executable instructions that, for example, instruct a computing device, a computer, a computing system, etc. For example, one or more modules may instruct a device or system to generate a graphical user interface for selection of regional geometry constraints for an environment, generate a graphical user interface for selection of pad and well specifications for the environment, generate a graphical user interface for selection of pad placement options for placement of pads in the environment; and generate a graphical user interface for selection of presenting a cost surface or presenting pad locations.

As an example, one or more modules may instruct a device or system to generate a graphical user interface for selection of presenting a cost surface and presenting pad locations, to generate a graphical user interface for selection of a plug-in to perform a pad placement process, to generate a graphical user interface for designing a well pad, etc. As an example, one or more modules may be implemented as or form a plug-in to a framework.

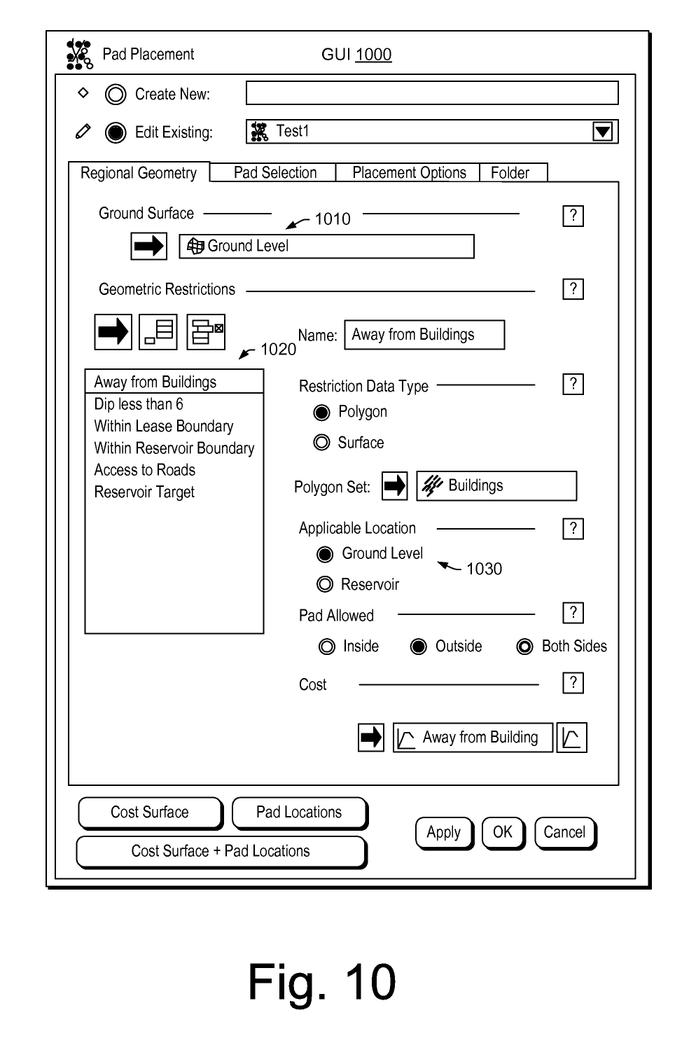

FIG. 10 shows an example of a graphical user interface 1000 for selecting geometric restrictions as inputs for a pad placement process (see, e.g., fields 1010, 1020 and 1030). In the example of FIG. 10, the ground surface or ground level field 1010 allows for specifying geometric restrictions, for example, as shown in field 1020 (e.g., away from buildings, dip less than 6, within lease boundary, within reservoir boundary, access to roads, and reservoir targets). The field 1030 provides graphical controls that allow for selection of applicable location, for example, a ground level or a reservoir (e.g., where the ground level may be an upper surface and the reservoir a lower surface). As mentioned, a probe may be defined and applied to various locations at an upper surface where restrictions of a lower surface are taken into account in assessing the various locations.

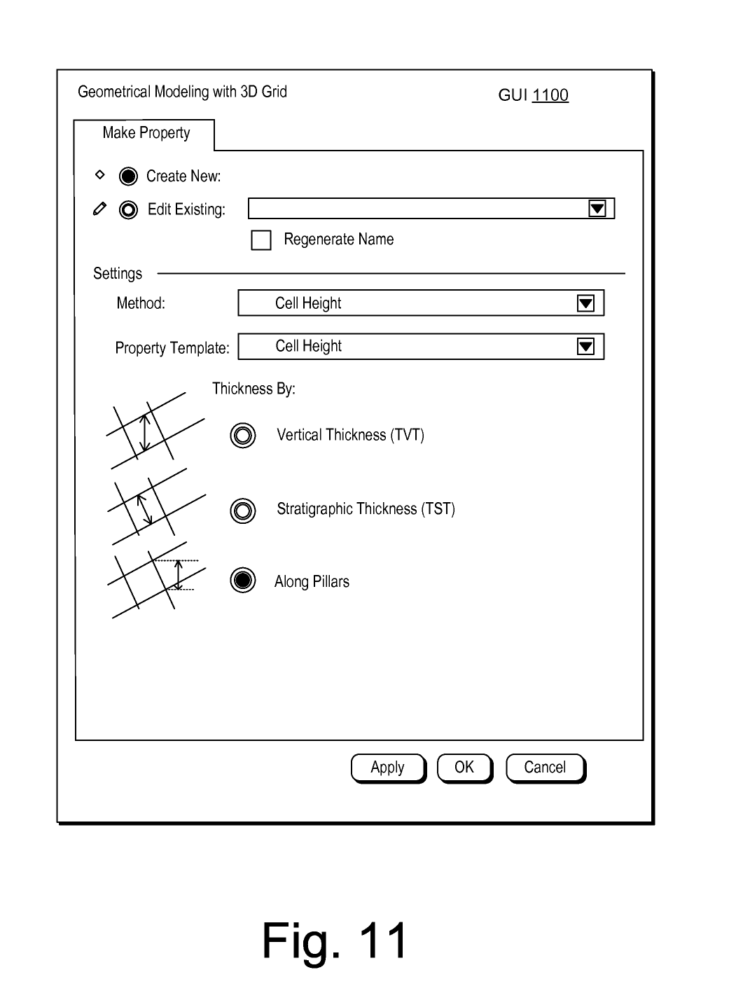

FIG. 11 shows an example of a graphical user interface 1100 for a property with respect to a three-dimensional grid (e.g., for defining a restriction). In such an example, a pad placement module can provide for creating a reservoir thickness surface attribute attained from a 3D grid property. A user may commence creation of the attribute by selecting a geometrical modeling process that renders the GUI 1100 to a display. In the example of FIG. 11, a field may appear for “cell height” and “method type” to generate a property called “cell height” (e.g., a model pane under a property folder). In response, a 3D window may open where the property may be toggled, for example, by selecting control next to the property's name. In such an example, color scaling may be implemented and optionally adjusted and a property filter function applied once a 3D grid has been selected. In a property filter control, a user may select a check box or other control to use a value filter in conjunction with a cell height property. In such an example, a user may adjust a scale for visualization of certain values, for example, greater than a selected value. In turn, a rendering algorithm may adjust property color such that a color change occurs to indicate that a filter is being applied. As an example, an option to make a map from a property may be presented and calculations may be applied on the filtered cells, for example, to create an average surface map (e.g., “average map for cell height”). Setting of the surface map may be available as well as a conversion process to convert information to a set of polygons along edge of a selected surface. As an example, a polygon set may be named “reservoir_boundary” and optionally moved into a “restrictions” folder (e.g., via a drag-and-drop operation). Thereafter, a user may access the created “reservoir_boundary” as a restriction in a pad placement process.

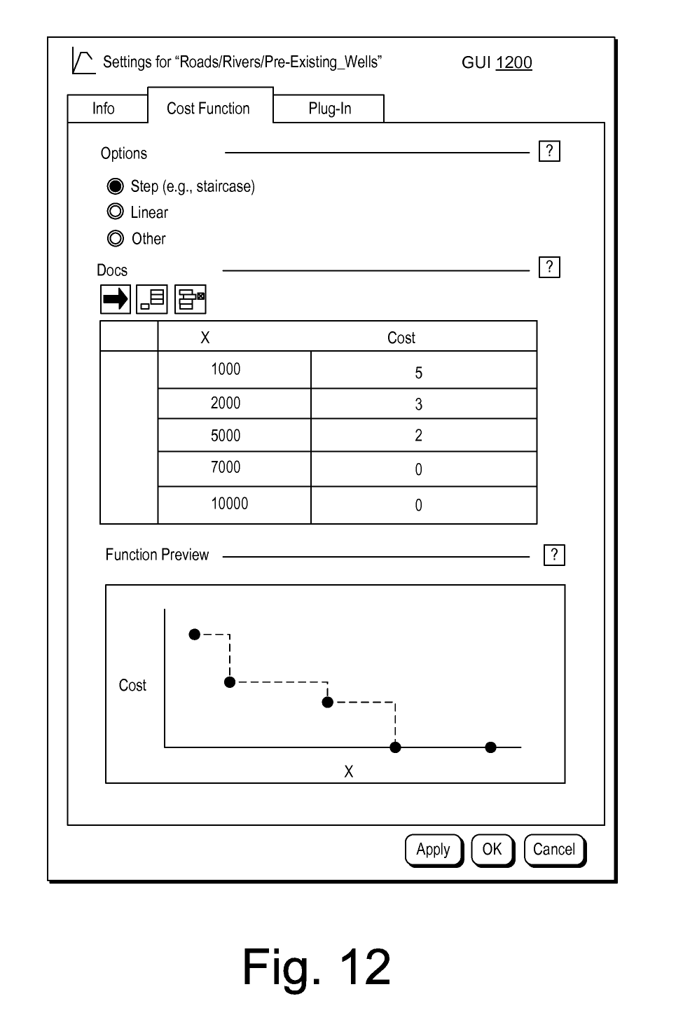

FIG. 12 shows an example of a graphical user interface 1200 for generating a cost function. As an example, a cost surface may aim to convey “drillable area” as where available pad locations are at an upper surface and a lower surface. In such an example, cost may be set to 0, for example, where a range of x-values denotes the closest a well can be drilled to an object or boundary. As an example, a scenario may indicate a ground level surface where there are no surface restrictions, and no costs tied to any attribute or border distance. In such an example, a drillable area may be an entire ground level surface, and the cost to drill may be 0 at any given location. Alternatively, as an example, a cost surface may contain more complexity. For example, other than indicating “drillable area,” it may also show cost conventions with respect to surface and reservoir-defined parameters, like rivers, cities, reservoir thickness, dip angle, etc. Such an approach can provide a user with an ability to incorporate many real-life decision-pending drilling parameters into a pad placement process.

As an example, a process can include one or more cost functions specified for each geometric restriction added to the process. A cost function may be specified in arbitrary units, for example, where “x” describes a relative distance or property value range to be considered in the cost function versus the relative “cost”. Such an approach can allow a user to create as many cost functions using a variety of inputs (either through a surface attribute, or polygons, or lines). For polygons, “x” may correspond to distance. For example, a cost scheme could be created where the closer a pad is to a corresponding object (e.g., an object such as in the PETREL® framework), the higher the cost of the pad/well. For example, a surface geometric restriction like “Rivers” may be represented by polygon lines. Logic may be conveyed as something like “we cannot drill within 500 feet of the river, it will be more expensive to drill within 500-1000 feet, and the cost will become less, the further we drill from the river”. For such logic, “x” can refer to a 2D distance to the polygon lines that represent the “Rivers” restriction. To indicate that it is not practical to drill within 500 feet of the associated polygon lines “Rivers,” the first “x” value may be 500. A default cost function may apply a 0 cost from an x-value of 0 to 10,000. If applied to polygon geometric restrictions, this means that a pad location can exist within 0 and 10,000 units from the dropped polygon. In such an example, a 0 x-value can be seen as a floor restriction and an x-value of 10,000 as a cap. In the example of FIG. 12, cost is shown as decreasing in a stepwise manner with respect to x.

As an example, a cost function can act to limit a drillable area, for example, where x-min and x-max values limit a proximity/range of “drillable” locations. In such an example, by limiting the minimum or maximum values of “x,” a user has the ability to limit or enable available drillable areas at the surface and reservoir levels. As an example, a cost function can establish a cost scheme relative to a surface property (e.g., a cost function may be based on a surface attribute). In such an example, a surface attribute such as z-depth can be used to show an increased well cost based on depth. As an example, a surface may have a property like NTG defined that can be used in a cost function to indicate non-drillable locations at a surface level to be available where NTG is less than a cost value. As an example, a cost function can establish a cost scheme relative to proximity of polygon lines. For example, a process may include one or more of roads, pipelines, property lines, etc. and: (a) where both sides of a polygon are selected, a cost function may be applied to each side of the polygon line; (b) where an inside is selected, items outside of the closed polygon may not be considered and the cost function may be applied to the inside of the polygon (e.g., for use to describe a lease area, reservoir boundary or some other confining restriction); or (c) where an outside is selected, items inside of the closed polygon may not be considered and the cost function may be applied to the outside of the polygon (e.g., examples may include cities, airfields, residential areas, where drilling may not be allowed within a given representative polygon, and may be more expensive the closer a pad is to the given polygon boundary, etc.).

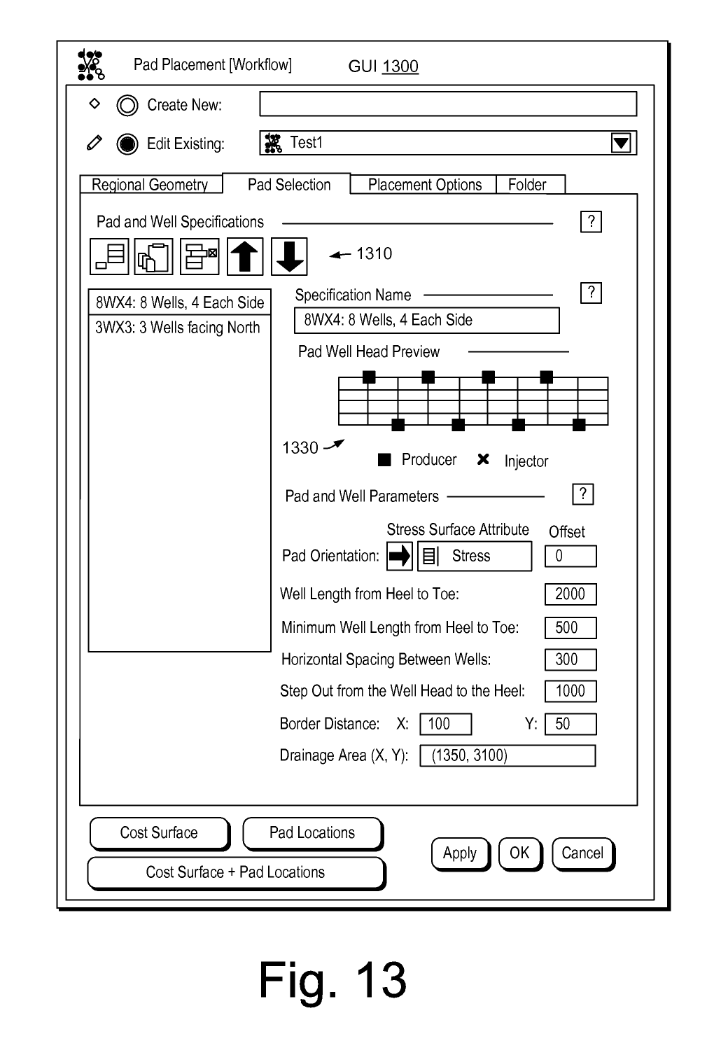

FIG. 13 shows an example of a graphical user interface 1300 for selecting pad and well specifications as inputs for a pad placement process (see, e.g., field 1310). For a selected input specification, a graphic 1330 may provide a representation as a pad well head preview. While pad selection is shown in the example of FIG. 13 (and various other examples), other type of equipment (e.g., structure, etc.) may be specified, configured, etc., and placement options provided (e.g., via execution of a probe-based method).

As an example, a pad placement process can consider a list of configurations sequentially: first, trying to use the first pad configuration, followed by the second configuration in the list, and so on. In such an example, if no pad configurations from the list are suitable, then a location may be left empty. As an example, a user may set up a process to start a list with the most desirable pad configuration to be considered first, the next most desirable pad configuration second, and so on, so that the least number of pads may be used to supply the most number of wells.

In the example of FIG. 13, the pad well head preview graphic 1330 may be generated by a pad placement module as a schematic to illustrate how different wells in a pad may be organized based on geometry specified, which may be, for example, in a form of an XML file (e.g., mark-up language). Such a graphic may show locations of individual wells with reference to a pad location (e.g., optionally via consumption of mark-up language or other instructions).

In the example of FIG. 13, for a pad selection tab of a pad placement process, a user may drop down or load the following well pad configurations 8WX4 and 3WX3; noting that other configurations can be added/edited (e.g., via an XML or other file). A user may, for a selected configuration, actuate a drop down for a stress attribute (e.g., stress direction) and review various associated parameters. As an example, a pad orientation field may provide for a pad's azimuth that indicates a degree orientation that a pad has and a sum of a surface attribute (e.g., dropped in the stress attribute field, plus the value in the offset field (e.g., by default it may be 0) can indicate an orientation for the pad. As an example, a placement options tab may allow for an option to automatically rotate a pad and to check various orientations (e.g., at specific increments) to determine a best orientation of a pad.

As to well length from heel to toe, this may be a length of a well from a heel point to a toe point of the well. Such a parameter may be used to determine a length of a horizontal lateral of a designed well. As to drainage area, this may be defined as a bounding box of points representing the heels and toes (e.g., on both sides). As an example, a drainage area calculation may be based on a 0 degree orientation, for example, to calculate a theoretical drainage area that may be affected by a well in a pad. As to a minimum well length from heel to toe, this may allow a user to set a minimum desired length, which if not met, may avoid well creation. If a default value of 0 is used, then the minimum well length may be a value entered in a well length from heel to toe field.

As to horizontal spacing between wells, such a parameter can specify spacing between heel (or toe) locations of two or more wells in a pad. As to step out from a well head to a heel, it may be a lateral distance allowed between a well head point and the heel point of a well trajectory. As an example, a border distance parameter may control minimum distance between wells in a neighboring pad (e.g., x and y distances that a nearest well from an adjacent pad may exist at with relation to the wells of a given pad).

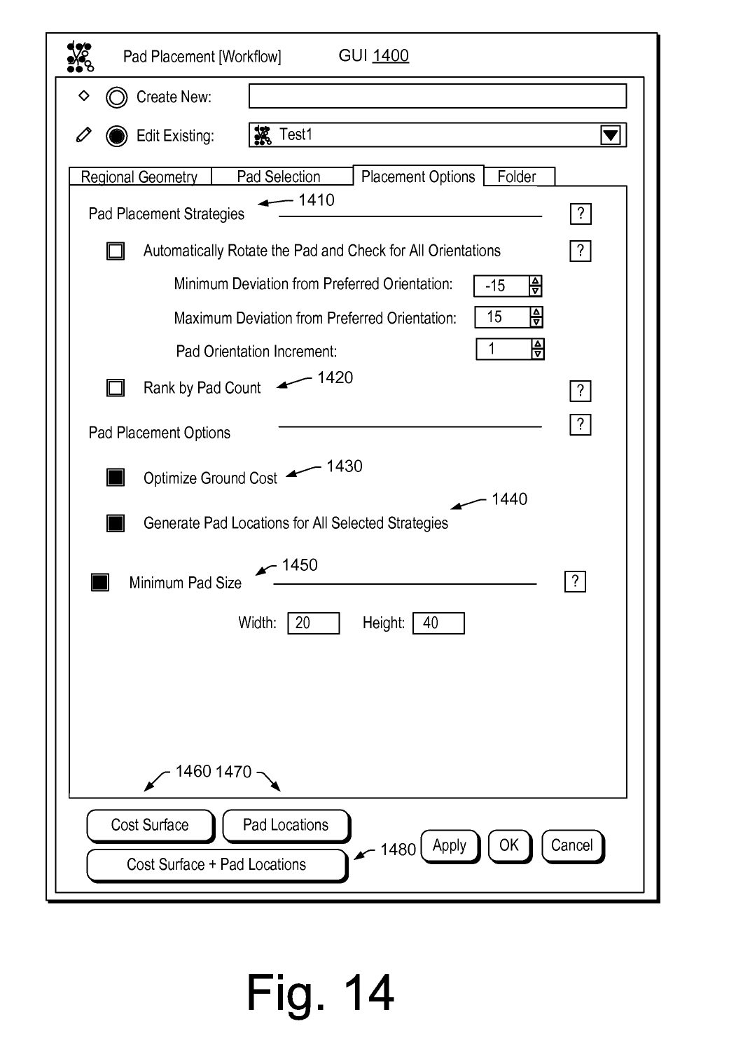

FIG. 14 shows an example of a graphical user interface 1400 for selecting placement options for a pad placement process (see, e.g., fields 1410, 1420, 1430, 1440 and 1450). Further control graphics or graphical controls 1460, 1470, and 1480 allow a user to select and a machine to receive instructions or commands to perform actions associated with a cost surface or surfaces, pad locations, or a cost surface or surfaces and pad locations.

As to “rank by pad count” (see, e.g., the field 1420), such a strategy may aim to further maximize a total pad count. For example, through such a selection, a number of top-listed pads that can be placed in an I-direction may be counted. Such a strategy may consider other combinations varying different applicable pad configurations in a pad selection list and, for example, select a best combination of pads (e.g., the option having the highest number of pad wells in the I-direction) as the final choice. Such a strategy first determine if a surface's I-direction coincides with a pad well orientation, for example, to see if a mismatch exists, which may impact a rank by pad count process.

As to “optimize ground cost” (see, e.g., 1430), as an example, a pad placement process may perform a cost minimization that will not remove pads, since a goal of the pad placement process may be to maximize reservoir contact, but rather will shift existing pad locations to reduce the total cost, if possible. For example, within the same increment a pad may be shifted from a ground location with a surface cost of 10 to a location with a surface cost of 8. In such an example, a new pad location after cost optimization may, for the same reservoir coverage, demonstrate a lesser cost.

As an example, a cost optimization process may be iterative as moving a pad from one location to another may enable additional movements for one or more pads nearby. As an example, a module can determine whether an iteration results in a lower cost, for example, such that if the module's process is stopped before it is complete, the module can output pad locations that bear no higher cost than the pad locations without the optimization. Such a process may be useful in demonstrating cost sensitivity between two potential pad locations. However, a first priority may be to maximize contact with a reservoir surface (e.g., a lower surface); thus, cost optimization may be applied as an adjustment to strategy-generated points.

As to “generate pad locations for selected strategies” (see, e.g., the field 1440), such an option can show pad locations for each selected strategy. As an example, if this option is not toggled on, a case with highest reservoir coverage may be output as a final pad locations point set.

As to “minimum pad size” (see, e.g., 1450), this may be used for selection of dimensions of a minimum pad size. For example, for a rectangular pad, a width and height may be provided; whereas, for a circular pad, a radius may be provided. Such an option may operate in conjunction with a pad geometry, for example, to display appropriate options that can define a minimum pad size.

As to the control 1460, this can initiate generation of cost surfaces for a ground level (e.g., upper level) and for a reservoir level (e.g., lower level). As an example, resulting surfaces can be found in a folder, for example, in an input pane. As an example, surfaces may be toggled on one at a time (e.g., in a 2D or 3D window) to verify that geometric restrictions were used in an intended way, for example, that the ground cost surface shows no cost surface area within it.

As to the control 1470, this can initiate generation of pad surface locations, for example, represented by a point-set. As an example, such a set may be visualized in a in a 2D or 3D window with surface restrictions to see how the pad locations were chosen with respect to these restrictions. In such an example, distance between a pad location and a restriction polygon may be viewed while referring to a respective cost function input. As an example, a pad placement point-set may be dropped into a pad well design input field. In such an example, well trajectories deviating from the pad well head may be created. As to the control 1480, this may be used to initiate both generation of cost surfaces and generation of pad surface locations.

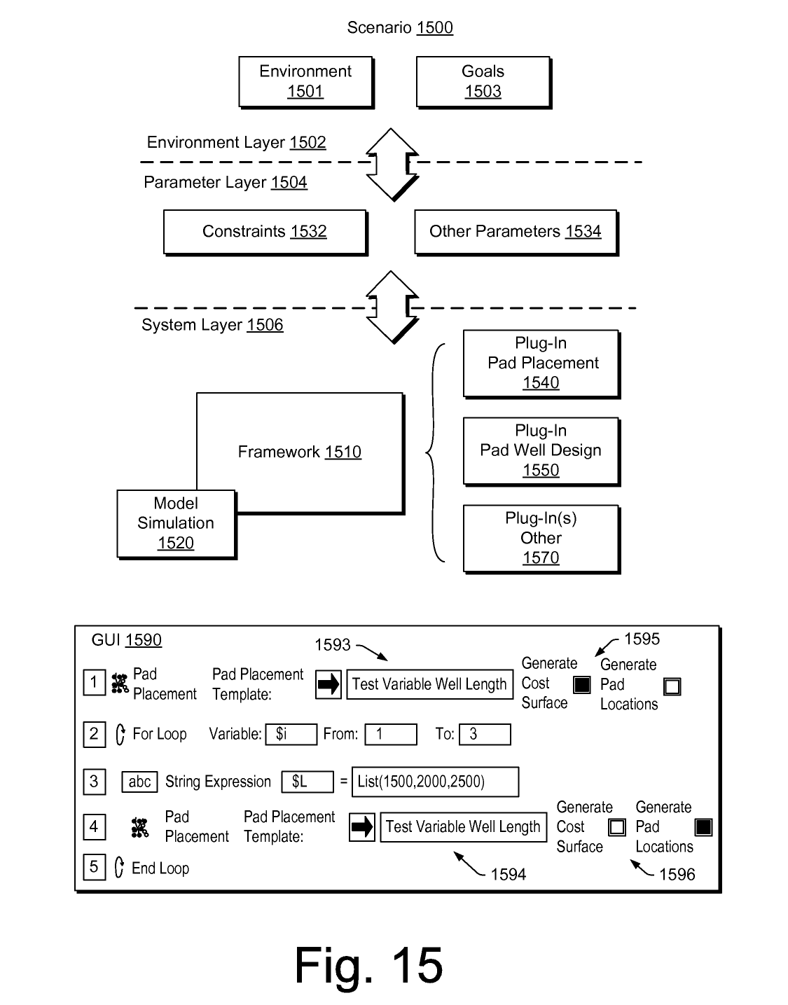

FIG. 15 shows an example of a scenario 1500 that includes an environment layer 1502, a parameter layer 1504 and a system layer 1506. In the example of FIG. 15, the environment layer 1502 accounts for an environment 1501 and goals 1503 associated with that environment. For example, the environment 1501 may be a field (e.g., including subsurface) that includes one or more reservoirs and the goals 1503 may be financial or other goals related to exploration, extraction, storage, etc., with respect to the field. The parameter layer 1504 includes constraints 1532 and other parameters 1534, which may be derived from the environment layer 1502. For example, if one of the goals 1503 is to drill a well in the environment 1501, then the parameter layer 1504 may include parameters (e.g., constraints or other) that characterize a pad configured to perform drilling.

In the example scenario 1500 of FIG. 15, the system layer 1506 includes a framework 1510 and a model simulation module 1520 where the framework 1510 can interact with one or more plug-ins such as a pad placement plug-in 1540, a pad well design plug-in 1550, and one or more other plug-ins 1570. For example, the framework 1510 may be or provide at least some features of the OCEAN® framework and the model simulation module 1520 may be or provide at least some features of the PETREL® simulation software framework.

As an example, the system layer 1506 may receive parameter values from the parameter layer 1504 and perform simulations where the simulations rely on input of at least some of the parameter values to one or more of the plug-ins 1540, 1550 and 1570. Output from a simulation may be directed to the parameter layer 1504, for example, for purposes of a sensitivity analysis, optimization, etc., and optionally to the environment layer 1502, for example, for purposes of gathering more information about the environment 1501, selecting another environment, adjusting or revising one or more goals 1503, or a combination thereof.

As to a sensitivity analysis, an example of a graphical user interface 1590 provides for testing variable well length via template input fields 1593 and 1594 according to options provided in selection boxes for cost surface generation 1595 and pad location generation 1596. Such an analysis can be integrated into the scenario 1500 with respect to the system layer 1506 and the other layers 1502 and 1504. The output of a sensitivity analysis may link environment 1501 and goals 1503 with respect to particular pad placement options, for example, based on constraints for acceptable pad configurations. As to the example of the GUI 1590, it demonstrates a script (see, e.g., 1, 2, 3, 4, and 5) that can set a well length to a list of values (1500, 2000, 2500) and generate pad locations, given each of these well lengths, to determine how sensitive pad locations are to such variations in well length.

As to optimization, as shown, the framework 1500 can interact with the plug-ins 1540, 1550 and 1570 and the simulation module 1520 to optimize one or more parameter values of the parameter layer 1532. For example, if a particular one of the goals 1503 is economic, then a cost function may be provided that depends on one or more of the parameters of the parameter layer 1506 where the framework 1510 optionally interacts with the plug-in 1570 that includes the cost function such that simulations, or more generally calculations, are performed in an iterative or other manner to maximize or minimize the cost function (e.g., depending on how the function may be cast). Once the cost function is optimized, for example, via interaction between the framework 1510 and the plug-in 1570 and optionally other layers 1504 and 1502, optimized parameter values as well as cost may be communicated or presented in a manner for consideration with respect to the environment 1501 and the goals 1503.

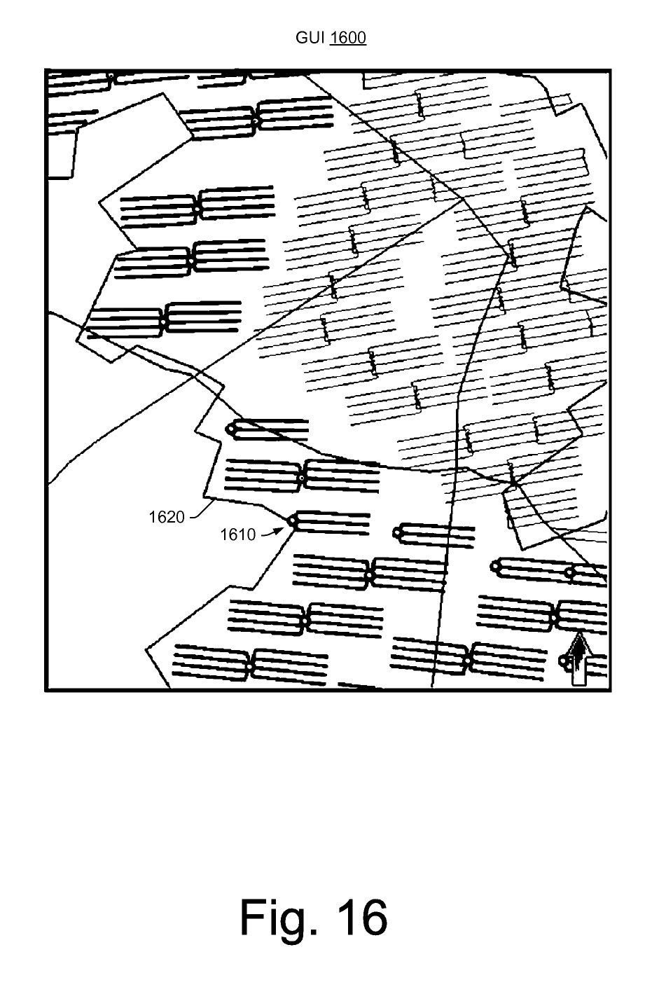

FIG. 16 shows an example of a graphical user interface 1600. In the example of FIG. 16, various lines are shown with respect to well points, which include wells extending therefrom. A pad placement process may, for example, provide data for rendering in such a manner to visualize output from the process and various constraints with respect to the output. In the example of FIG. 16, a well point 1610 is shown as including various well paths extending in a direction away from a boundary 1620, for example, which may represent a reservoir boundary, a lease boundary, etc. As an example, various well points, boundaries, etc., may be selected (e.g., via an input device such as a mouse, a touch screen, etc.) where options may be presented in a menu or other form, for example, to view additional information, to edit information, etc. As an example, a tool may be available to position, rotate, etc., one or more well points, paths, boundaries, etc., optionally for consideration as input to a revised plan.

As an example, a method can include adjusting (e.g., systematically) one or more parameters values (e.g., constraints, pad configuration, etc.) to determine how sensitive one or more results (e.g., simulation output) is with respect to the one or more parameters. For example, such a sensitivity analysis may look for economic sensitivity, production sensitivity, etc., to a single parameter or to multiple parameters. As an example, a method can include adjusting one or more parameter values (e.g., for constraints, pad configurations, etc.) by an optimizer to maximize a value such as production from wells proposed to be drilled from one or more pads.

As an example, a pad placement module can provide for user input, for example, to allow a user to experiment with different pad configuration parameters, such as well length or others and to determine the best parameter to be used for the field development.

As an example, a method can include adjusting at least one of a constraint value, a pad configuration definition value, or a constraint value and a pad configuration definition value; and generating pad locations to determine sensitivity of specifications for the generated pad locations to the adjusting of the at least one value. As an example, a method can include providing a function that depends on at least one of a constraint value, a pad configuration definition value, or a constraint value and a pad configuration definition value; and optimizing output of the function by generating pad locations responsive to adjusting at least one of the at least one value of the function.

As an example, a workflow process may optionally be a process associated with the geologic environment 150 of FIG. 1 (e.g., surveying, building, sensing, drilling, injecting, extracting, modeling, simulating, etc.). For example, output from a pad placement process may aid in surveying, building, operating, etc., a pad or related equipment. As an example, consider a workflow that includes communication of information as to pad placement options via a network to equipment located at a site (e.g., computer, cell phone, specialized equipment, etc.). Such information may assist with a survey that acquires additional information and that communicates that additional information to equipment for further optimizing pad placement options. For example, information requesting more detailed survey (e.g., locations of restrictions, soil conditions, etc.) may be communicated and, in response, return data from the more detailed survey to hone placement options.

As an example, a pad placement process or a system for pad placement may, for example, further operate or be configured to control machinery, equipment, or communicate location data to separate devices to influence the operation of those devices in a drilling or pad placement operation. As an example, once a suitable pad placement location is determined, separate devices, such as machinery for drilling, earth moving, etc., may be controlled to construct a pad, place wells via the pad, travel to a pad location, or be otherwise affected in a drilling, pad placement or other associated operation.

As an example, a pad placement product may optionally be suitable to expand capability of the aforementioned PETREL® framework, for example, by offering a solution for regional well planning for shale gas producers and oil sand producers. Such a product may be applied to environments of interest in North America and other environments as drilling for shale gas expands (e.g., to other continents).

When developing a regional field of shale gas or oil sand reservoirs, operators may consider drilling multiple wells from the same well pad location in an effort to maximize a return on investment. As an example, wells drilled at each pad may follow one of several standard configurations. For example, a well head configuration can include a row of 4 producer wells located next to a row of 4 injector wells for SAGD development in an oil sand reservoir. Operators may choose well pad locations based on a combination of constraints at the ground level, such as roads, rivers, buildings, etc., and constraints at the reservoir level, such as lease boundary. A concern of the operators can be selection of pad locations and configurations to achieve more reservoir coverage. Among alternatives that produce the same reservoir coverage, a secondary concern can be selection of pad locations that incur lower cost. As an example, various approaches can optionally address both concerns.

As mentioned, a pad placement process may operate in conjunction with a pad well design process, which may be a plug-in for creation of proposed wells on regular configurations (e.g., to be repeated at each pad location), to produce detailed well designs. Applications for such a process are reservoirs with high well density, such as shale gas or heavy oil. Such a process may seek to control or define well length, vertical and horizontal spacing, orientation, etc.

As an example, a method can include selecting well pad locations and configurations, which conform to constraints both at the ground level, such as roads and surface gradients, and at the reservoir level, such as lease boundaries. A system may be provided to implement such a method where the system allows operators to define their own pad configurations to be used for the field development. In turn, such a system may generate probes from selected pad configurations, and apply the probes to combined constraints to produce well pad locations and pad configurations parameters at each location.

As an example, one or more modules may optionally allow for integration into framework, which, in turn, allows for overall optimization by varying certain parameters, such as well length or pad orientation, in pad configurations. Such an approach can allow a user to experiment with different parameters and determine the best parameters for a development. Such a process may be aided by optimization processes (e.g., automated or semi-automated optimization to reduce manual demands). As an example, a method may include ranking well pad locations, which may help producing pad locations with higher reservoir coverage.

As an example, a method for placing well pads may be implemented, for example, during a regional development planning of a shale gas or oil sand field. In such a method, in addition to the geological and petrophysical characteristics of a reservoir, other factors may be considered during the planning process, such as access to existing roads, avoidance of buildings, etc. Further, as operators often have more than one pad configurations, such a method can include input of various configuration characteristics to define possible pads.

As an example, a pad placement process can provide a way for a user to capture a ground surface and other ground level constraints, for example, using a combination of surfaces, polygons and cost functions. Examples of ground level constraints include, but are not limited to, access to existing roads, avoidance of towns, rivers and cliffs, etc. Such physical constrains may be represented by either polygons or surfaces when such a process is implemented (e.g., optionally in conjunction with the PETREL® framework).

As an example, a pad placement process can utilize one or more cost functions to translate physical constraints such as distances, dips, etc., into normalized costs representing an operators' preference for different physical constraints. A process can optionally allow a user to define one or more cost functions, for example, at different levels of details. For example, along a spectrum, at one end a normalized cost may be either as zero (e.g., null) or not defined, indicating either drillable or non-drillable conditions; whereas, at another end, the normalized cost can be representative to the real cost for drilling under different physical conditions, which enables a method to perform cost optimization in a more realistic way. Such a method may provide a way for a user to capture constraints at the reservoir level using surfaces, polygons and cost functions.

As an example, a system for performing a pad placement process may optionally include a sub-system that combines constraints into, for example, two cost surfaces (e.g., at the ground level and the reservoir level) for representing combined costs. In such an example, for each grid node location of an upper surface, the sub-system calculates a normalized cost at the location for each specified constraint, and assigns the sum of the normalized cost of the individual constraint as the combined cost at the location.

As an example, a system may optionally provide a way for operators to define a set of standard well pad configurations that can be selected by a user. For example, each pad configuration may be made up with one or more well configurations, and a well configuration may be described by coordinates of at least three control points (e.g., well head, heel and toe; see, e.g., FIG. 2). In such an example, coordinates of the control points can be specified using either Cartesian coordinates or cylindrical coordinate system. Arithmetical expressions of numbers and pre-defined variables can then be used to specify the actual coordinates. Such an approach gives a user the option to vary certain parameters, such as well length and pad orientation, for the same pad configuration. Further, given such added flexibility, integration into a framework (e.g., consider the PETREL® framework) can, in turn, allow a user to experiment with different configuration parameters quickly in the search for better field development options.

As an example, a method can include converting a pad configuration into a probe, for example, a 2-dimensional array representing relative positions between a location at a ground level (upper level or surface) and covered reservoir area at a reservoir level (lower level or surface). Given such a probe (or probes), shifting the probe across a two-dimensional ground surface grid can provide for determination of valid ground locations where the corresponding pad configuration of the probe may be placed, at least according to the method constraints. Such a method may optionally include generating a pad allocation plan (e.g., a blueprint), which serves as the basis for additional pad placement options (e.g., optionally in conjunction with features of a framework such as the OCEAN® framework as configured to host the PETREL® framework).

As an example, many variations can exist among different pad placement problems, as each region has its own physical constraints. As an example, a system can optionally provide for different placement options that could produce better placement results under different scenarios. For example, a user may selectively enable additional placement options based on user preference and applicability of a placement option. As an example, one of these options may use a ranking system based on a number of top pad selection that can be placed at each unique grid line, and find line combinations that allow the most number of pads to be place in the region. Such an option can produces a best result, for example, when a user wants to place pads in the same orientation as the grid line.

As an example, a method may optionally provide for analysis with respect to fracking operations. For example, factors such as orientation of a well with respect to a stress map of natural stress directions may indicate placement locations for pad to drill wells orthogonal to the natural stress directions (e.g., as fracking may be applied to provide for fractures along natural stress directions).

As an example, a surface or level may be a projection. For example, a reservoir as a three-dimensional structure may be projected to a two-dimensional surface, which may be a lower surface of a model. As an example, other three-dimensional structure may be projected to a two-dimensional surface, which may be an upper surface of a model (e.g., a ground level surface). Such structure may not be at ground level, for example, where infrastructure such as water, sewer, etc., may be buried under ground, it may be within a zone or of such a character (e.g., to be avoided by underground drilling, piping, etc.) that it is projected to an upper surface. Further, for structures that extend above ground, such as elevated power lines, buildings, flight paths for aircraft, these may be projected to an upper surface (e.g., a ground level surface). In general, a constraint may be indicated, assigned or defined by a line, a polygon, a surface, etc., in relationship to one or more model surfaces.

As to objects or other constraints that may impact pad placement or other concerns, such objects may optionally be represented as polygonal or other two-dimensional shapes. For example, for an iceberg with some expected variation in space over time (e.g., lifetime of an operation), the entire expected area may be input as a constraint, optionally with some cost associated if it may deviate or if movement (e.g., by artificial means) is possible at some cost.

As an example, options may be available for new fields and existing fields. For example, a method can include loading locations of existing wells and reevaluation of the wells, optionally for placement of pads for new wells. In such a method, characteristics such as drainage of a reservoir, injection of steam, fracking, etc., may be accounted for when performing an analysis for placement of one or more new pads for drilling wells.

As an example, a method may include path interference based preliminarily on projections and secondarily on depth to ascertain whether two paths will cross in physical space or otherwise be located in proximity to each other in violation of a constraint or constraints (e.g., regulatory, physical, operational, etc.). A module that includes instructions to perform a path interference analysis may be provided and optionally implemented as an option selected via a graphical user interface. Such an option may allow for input of zones (e.g., depth) with associated constraints or constraints based on type of structure or feature to be avoided (e.g., 20 meters from a steam injection line and 40 meters from a production line). Again, as an example, invocation of such constraints may occur responsive to a projection based analysis for intersecting or closely approaching lines (e.g., at least some of which may be representative of structures or features to be added to an environment).

As an example, various technologies and techniques may apply to situations where surface restrictions on a drilling center, whether drilling is associated with oil, gas, injection, extraction, water, carbon sequestration (e.g., storage), or other operations. Further, output from a method may include information for one or more agencies or regulatory entities. For example, output may be provided to a power utility company to indicate pad placement locations with respect to easements. In other words, the output may be beneficial to multiple parties with property rights, mineral rights, water rights, etc., in an environment.

As an example, one or more modules may be configured for stand-alone implementation using a computing device, system, etc., or configured for bundling with other modules as part of a workflow or workflows. As an example, output of a pad placement method or system may be locations for one or more pads and optionally parameters associated with a selected pad configuration, such as the well length and pad orientation. A system may be configured to render output of pad location(s), for example, via a 3D graphic or a map for visualization, transmit output to a file in a storage device (e.g., optionally as a spreadsheet file).

As an example, output may be consumed directly by one or more other plug-ins (e.g., optionally OCEAN® framework or other), for example, to provide for workflows that may produce hundreds or thousands of projected well paths directly from the various constraints and pad configurations selected for an entire region.

As an example, one or more computer-readable media may include computer-executable instructions to instruct a computing system to output information for controlling a process. For example, such instructions may provide for output to a sensing process, an injection process, a drilling process, an extraction process, etc. Such instructions may be communicated via one or more networks (e.g., cellular, satellite, Internet, etc.).

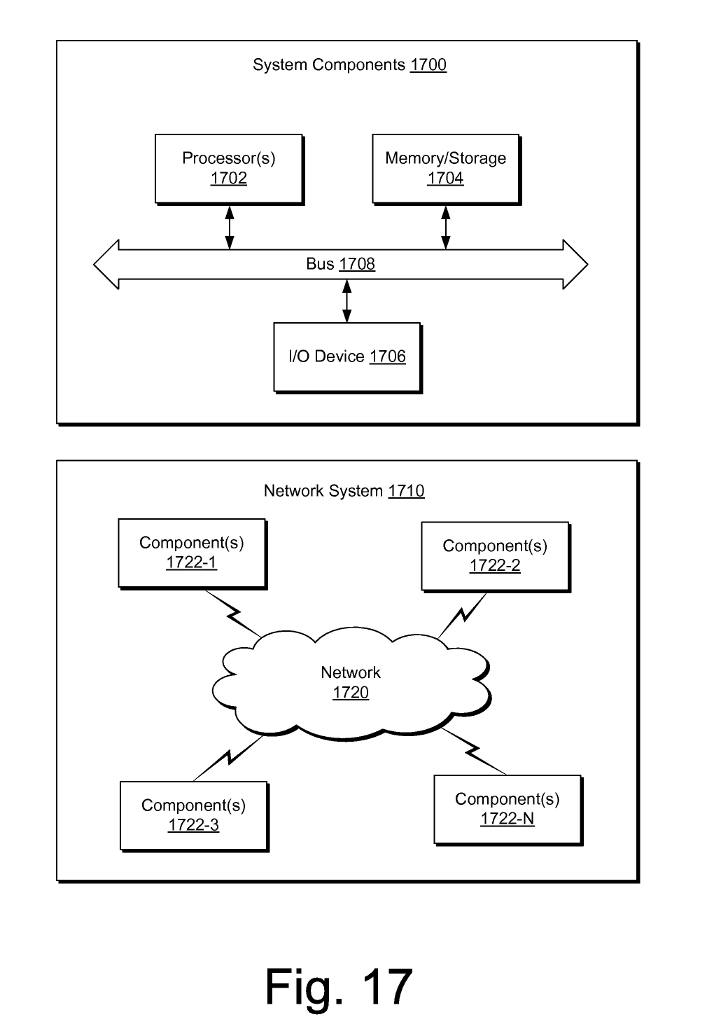

FIG. 17 shows components of a computing system 1700 and a networked system 1710. The system 1700 includes one or more processors 1702, memory and/or storage components 1704, one or more input and/or output devices 1706 and a bus 1708. As an example, instructions may be stored in one or more computer-readable media (e.g., memory/storage components 1704). Such instructions may be read by one or more processors (e.g., the processor(s) 1702) via a communication bus (e.g., the bus 1708), which may be wired or wireless. The one or more processors may execute such instructions to implement (wholly or in part) one or more attributes (e.g., as part of a method). A user may view output from and interact with a process via an I/O device (e.g., the device 1706). As an example, a computer-readable medium may be a storage component such as a physical memory storage device, for example, a chip, a chip on a package, a memory card, etc. (e.g., a computer-readable storage medium).

As an example, components may be distributed, such as in the network system 1710. The network system 1710 includes components 1722-1, 1722-2, 1722-3, . . . 1722-N. For example, the components 1722-1 may include the processor(s) 1702 while the component(s) 1722-3 may include memory accessible by the processor(s) 1702. Further, the component(s) 1702-2 may include an I/O device for display and optionally interaction with a method. The network may be or include the Internet, an intranet, a cellular network, a satellite network, etc.

Although a few example embodiments have been described in detail above, those skilled in the art will readily appreciate that many modifications are possible in the example embodiments without materially departing from the embodiments of the present disclosure. Accordingly, such modifications are intended to be included within the scope of this disclosure as defined in the following claims. In the claims, means-plus-function clauses are intended to cover the structures described herein as performing the recited function and not just structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures. It is the express intention of the applicant not to invoke 35 U.S.C. §112, paragraph 6 for any limitations of any of the claims herein, except for those in which the claim expressly uses the words “means for” together with an associated function.

1. A method comprising:
assigning one or more constraints to an upper surface;
assigning one or more constraints to a lower surface;
defining a pad configuration;
generating pad locations locatable on the upper surface that conform to the defined pad configuration and the assigned constraints for the upper surface and the lower surface; and
outputting specifications at least one of the generated pad locations.

2. The method of claim 1 wherein the assigning one or more constraints to an upper surface or to a lower surface comprises assigning a cost constraint.

3. The method of claim 1 wherein the assigning one or more constraints to an upper surface or to a lower surface comprises assigning a physical, environmental constraint.

4. The method of claim 1 further comprising adjusting at least one of a constraint value, a pad configuration definition value, or a constraint value and a pad configuration definition value; and generating pad locations to determine sensitivity of specifications for the generated pad locations to the adjusting of the at least one value.

5. The method of claim 1 further comprising providing a function that depends on at least one of a constraint value, a pad configuration definition value, or a constraint value and a pad configuration definition value; and optimizing output of the function by generating pad locations responsive to adjusting at least one of the at least one value of the function.

6. The method of claim 1 wherein the lower surface comprises a two- dimensional representation of a reservoir.

7. The method of claim 1 wherein the generating uses, at least in part, parameter values determined by applying a probe to locations on the upper surface.

8. The method of claim 7 wherein the probe comprises a two-dimensional probe or a three-dimensional probe.

9. The method of claim 1 further comprising defining a probe based at least in part on the defined pad configuration and applying the probe to locations on the upper surface to determine parameter values.

10. The method of claim 9 wherein the generating pad locations locatable on the upper surface comprises ranking locations on the upper surface based at least in part on the determined parameter values.

11. One or more computer-readable storage media comprising processor-executable instructions to instruct a computing system to:
receive constraint information for a multilayer model of an environment;
receive configuration information for a drilling pad;
generate a ranking of drilling pad locations based on the constraint information, the configuration information and the multilayer model of the environment;
present, via a graphical user interface, at least some of the ranked drilling pad locations; and
output specifications for at least one of the drilling pad locations based on input received via the graphical user interface.

12. The one or more computer-readable storage media of claim 11 wherein the instructions to instruct a computing system to output specifications comprise instructions to output a blueprint of a building site for building a drilling pad at one of the drilling pad locations.

13. The one or more computer-readable storage media of claim 11 wherein the instructions to instruct a computing system to output specifications comprise instructions to output a building costs for building a drilling pad at one of the drilling pad locations.

14. The one or more computer-readable storage media of claim 11 wherein the instructions to instruct a computing system to output specifications comprise instructions to output operational specifications for operation of equipment that may be placed via the drilling pad location.

15. The one or more computer-readable storage media of claim 11 wherein the instructions to instruct a computing system to receive configuration information for a drilling pad comprise instructions to receive configuration information for an offshore drilling pad.

16. One or more computer-readable storage media comprising processor-executable instructions to instruct a computing system to:
generate a graphical user interface for selection of regional geometry constraints for an environment;
generate a graphical user interface for selection of pad and well specifications for the environment;
generate a graphical user interface for selection of pad placement options for placement of pads in the environment; and
generate a graphical user interface for selection of presenting a cost surface or presenting pad locations.

17. The one or more computer-readable storage media of claim 16 wherein the instructions to instruct a computing system to generate a graphical user interface for selection of presenting a cost surface and presenting pad locations.

18. The one or more computer-readable storage media of claim 16 wherein the instructions to instruct a computing system to generate a graphical user interface for selection of a plug-in to perform a pad placement process.

19. The one or more computer-readable storage media of claim 16 wherein the instructions to instruct a computing system comprise a plug-in to a framework.

20. The one or more computer-readable storage media of claim 16 wherein the instructions to instruct a computing system to generate a graphical user interface for designing a well pad.
